(19) United States
(12) Patent Application Publication
(10) Pub. No.: US 2004/0029044 A1
(43) Pub. Date: Feb. 12, 2004

(54) Photocurable composition

(75) Inventors: Richard L. Severance, Stillwater, MN (US); Caroline M. Ylitalo, Stillwater, MN (US); Peter T. Elliott, Woodbury, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 10/214,619

(22) Filed: Aug. 8, 2002

(51) Int. Cl. G03F 7/027

(52) U.S. Cl. 430/281.1; 430/302; 430/325

(57) ABSTRACT

A photocurable composition comprises: at least one free-radically polymerizable material, at least one benzophenone derivative, at least one acylphosphine oxide, and at least one maleimide having the formula:

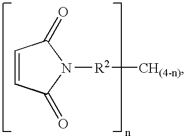

wherein

each R² independently represents a divalent organic group or a covalent bond, and

n is 1, 2, or 3.

The photocurable composition may be applied to substrate and cured by exposure to actinic radiation.

### TECHNICAL FIELD

The present invention relates to photocurable compositions. In one embodiment, the present invention relates to photocurable compositions that can be printed using an ink jet printer.

### BACKGROUND

In recent years, there has been an effort in industry to develop photocurable materials that may be used in coating and printing processes (e.g., as protective clear coats or inks).

Photocurable materials typically contain one or more polymerizable materials (e.g., a mixture of free-radically polymerizable monomers and/or oligomers) and one or more photoinitiators.

Typically, the productivity (i.e., speed) of processes utilizing photocurable materials depends, at least in part, on the amount of actinic radiation (i.e., radiation having at least one wavelength in the ultraviolet or visible region of the spectrum) required to achieve a desired degree of cure (i.e., polymerization and/or crosslinking) of the photocurable material. Insufficient curing may result in inadequate surface cure of the material (e.g., a printed image) and/or poor curing of the full thickness of the layer (i.e., poor through cure), which may cause poor adhesion of the cured material to the substrate on which it is printed and/or handling problems. Due to the nature of typical commercial printing processes and the presence of light absorbing colorants, cure speed and through cure are typically important variables in formulating and utilizing photocurable inks.

Photocurable inks are typically formulated by including colorant in the photocurable composition. Photocurable inks may offer advantages over conventional inks. For example, uncured ink images printed using photocurable inks can typically be made permanent (i.e., fixed) by exposure to actinic radiation. Immediately after fixing the image, it may typically be handled without risk of damage (e.g., by smearing). The problems of insufficient and/or slow curing may be particularly troublesome, if photocurable material is applied to porous materials (e.g., woven or nonwoven fabrics). In such instances, penetration of the photocurable material into the porous material may result in a relatively thick layer of photocurable material and/or attenuation of the amount of actinic radiation that is available for curing the full thickness of the photocurable material. These problems may be even more pronounced if the photocurable material is an ink.

Thus, there is a continuing need for photocurable materials, including inks, that rapidly cure when exposed to actinic radiation.

### SUMMARY

In one aspect, the present invention provides a photocurable composition comprising:

at least one free-radically polymerizable material;

at least one benzophenone derivative;

at least one acylphosphine oxide; and

at least one maleimide having the formula:

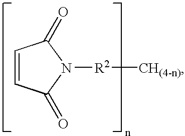

wherein

each R² independently represents a divalent organic group or a covalent bond, and

n is 1, 2, or 3.

In one aspect, the present invention provides a method for applying a photocurable composition to a substrate comprising:

providing a substrate;

providing a photocurable composition comprising:

at least one free-radically polymerizable material;

at least one benzophenone derivative;

at least one acylphosphine oxide; and

at least one maleimide having the formula:

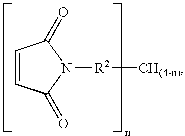

wherein

each R² independently represents a divalent organic group or a covalent bond, and

n is 1, 2, or 3; and

applying the photocurable composition to the substrate.

In another aspect of the present invention, an article comprises a substrate having thereon a reaction product of a photocurable composition comprising:

at least one free-radically polymerizable material;

at least one benzophenone derivative;

at least one acylphosphine oxide; and

at least one maleimide having the formula:

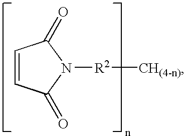

wherein

each R² independently represents a divalent organic group or a covalent bond, and

n is 1, 2, or 3.

In some embodiments of the present invention, the photocurable compositions further contain at least one colorant.

In some embodiments of the present invention, the photocurable compositions are useful for ink jet printing applications.

### DETAILED DESCRIPTION

Photocurable compositions of the present invention typically comprise at least one, preferably a mixture of two or more, free-radically polymerizable materials, the specific choice of free-radically polymerizable materials being determined by the specific properties sought (i.e., hardness, toughness, flexibility).

Typically, the total amount of free-radically polymerizable material(s) present in photocurable compositions of the present invention is in a range of from about 25 percent by weight to about 98 percent by weight free-radically polymerizable material(s), based on the total weight of the photocurable composition, although other amounts may be used. Preferably, the total amount of free-radically polymerizable material(s) is in a range of from about 30 percent by weight to about 95 percent by weight, more preferably from about 50 percent by weight to about 90 percent by weight, based on the total weight of the photocurable composition.

Free-radically polymerizable materials include, for example, free-radically polymerizable monomers and/or oligomers, either or both of which may be monofunctional or multifunctional. Free-radically polymerizable materials suitable for use in practice of the present invention are well known in the art, and include those described in, for example, U.S. Pat. Nos. 5,395,863 (Burns et al.); and 5,275,646 (Hudd et al.); and U.S. Pat. Publication No. 2002/0086914 A1 (Lee et al.), published Jul. 4, 2002; the disclosures of which are incorporated herein by reference.

Exemplary free-radically polymerizable monomers include styrene and substituted styrenes (e.g., α-methylstyrene); vinyl esters (e.g., vinyl acetate); vinyl ethers (e.g., butyl vinyl ether); N-vinyl compounds (e.g., N-vinyl-2-pyrrolidone, N-vinylcaprolactam); acrylamide and substituted acrylamides (e.g., N,N-dialkylacrylamide); and acrylates and/or methacrylates (i.e., collectively referred to herein as (meth)acrylates) (e.g., isooctyl (meth)acrylate, nonylphenol ethoxylate (meth)acrylate, isononyl (meth)acrylate, diethylene glycol (meth)acrylate, isobornyl (meth)acrylate, 2-(2-ethoxyethoxy)ethyl (meth)acrylate, 2-ethylhexyl (meth)acrylate, lauryl (meth)acrylate, butanediol mono(meth)acrylate, β-carboxyethyl (meth)acrylate, isobutyl (meth)acrylate, cycloaliphatic epoxide, α-epoxide, 2-hydroxyethyl (meth)acrylate, (meth)acrylonitrile, maleic anhydride, itaconic acid, isodecyl (meth)acrylate, dodecyl (meth)acrylate, n-butyl (meth)acrylate, methyl (meth)acrylate, hexyl (meth)acrylate, (meth)acrylic acid, N-vinylcaprolactam, stearyl (meth)acrylate, hydroxy functional polycaprolactone ester (meth)acrylate, hydroxyethyl (meth)acrylate, hydroxymethyl (meth)acrylate, hydroxypropyl (meth)acrylate, hydroxyisopropyl (meth)acrylate, hydroxybutyl (meth)acrylate, hydroxyisobutyl (meth)acrylate, tetrahydrofurfuryl (meth)acrylate, ethylene glycol di(meth)acrylate, hexanediol di(meth)acrylate, triethylene glycol di(meth)acrylate, tetraethylene glycol di(meth)acrylate, trimethylolpropane tri(meth)acrylate, ethoxylated trimethylolpropane tri(meth)acrylate, glycerol tri(meth)acrylate, pentaerythritol tri(meth)acrylate, pentaerythritol tetra(meth)acrylate, and neopentyl glycol di(meth)acrylate).

Exemplary commercially available free-radically polymerizable oligomers include those acrylated oligomers available under the trade designation “EBECRYL” from UCB Chemicals, Smyrna, Georgia (e.g., “EBECRYL 220”, “EBECRYL 80”, “EBECRYL 230”, “EBECRYL 244”, “EBECRYL 284”, “EBECRYL 8402”, “EBECRYL 5129”, “EBECRYL 4833”, “EBECRYL 4835”, or “EBECRYL 8301”), and acrylated oligomers available from Sartomer Company, Exton, Pa. (e.g., acrylated oligomers having the trade designations “CN501”, “CN502”, “CN550”, or “CN551”).

Preferably, free-radically polymerizable multifunctional monomers and oligomers are di- or tri-functional, and are preferably present in photocurable compositions of the present invention in an amount in a range of from about 1 weight percent to about 70 weight percent, more preferably in an amount in a range of from about 10 weight percent to about 60 weight percent, based on the total weight of the photocurable composition.

Photocurable compositions of the present invention typically include at least one benzophenone derivative (i.e., a compound having the benzophenone skeletal structure). Benzophenone derivatives and methods for making them are well known in the art, and are described in, for example, U.S. Pat. No. 6,207,727 (Beck et al.), the disclosures of which are incorporated herein by reference.

Exemplary benzophenone derivatives include symmetrical benzophenones (e.g., benzophenone, 4,4′-dimethoxybenzophenone, 4,4′-diphenoxybenzophenone, 4,4′-diphenylbenzophenone, 4,4′-dimethylbenzophenone, 4,4-dichlorobenzophenone); asymmetric benzophenones (e.g., chlorobenzophenone, ethylbenzophenone, benzoylbenzophenone, bromobenzophenone); and free-radically polymerizable benzophenones (e.g., acryloxyethoxybenzophenone). Benzophenone itself is inexpensive, and may be preferable if cost is a factor. Polymerizable benzophenones may be useful if residual odor or volatiles are a concern, and may be preferable for those applications as they become covalently incorporated into the composition during cure.

Many benzophenone derivatives are readily available from vendors such as, for example, Aldrich Chemical Company, Milwaukee, Wis., or Sartomer Company.

Photocurable compositions of the present invention typically include at least one acylphosphine oxide. Acylphosphine oxides and methods for making them are well known in the art and are described in, for example, U.S. Pat. No. 4,710,523 (Lechtken et al.), the disclosure of which is incorporated herein by reference.

Exemplary acylphosphine oxides include 2,4,6-trimethylbenzoyldiphenylphosphine oxide (e.g., as available under the trade designation “LUCIRIN TPO” from BASF Corporation, Mount Olive, N.J.), and bis(2,4,6-trimethylbenzoyl)phenylphosphine oxide (e.g., as available under the trade designation “IRGACURE 819” from Ciba Specialty Chemicals, Tarrytown, N.Y.).

Photocurable compositions of the present invention typically include at least one maleimide having the formula:

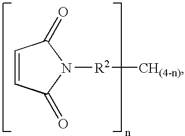

wherein

each R² independently represents a divalent organic group or a covalent bond, and

n is 1, 2, or 3.

Exemplary divalent groups include substituted or unsubstituted alkylene (e.g., alkylene having from about 1 to about 18 carbon atoms), substituted or unsubstituted arylene (e.g., arylene having from about 6 to about 18 carbon atoms), substituted or unsubstituted aralkylene (e.g., aralkylene having from about 7 to about 19 carbon atoms), and substituted or unsubstituted alkarylene (e.g., alkarylene having from about 7 to about 19 carbon atoms). The divalent group or groups (e.g., in cases where n=2 or 3) may independently be substituted with one or more additional groups attached to and/or within the skeleton of the divalent group (e.g., alkyl, halo, oxo, thia, oxa, aza, hydroxy, alkoxy, thioalkoxy, acyloxy). The divalent group may be linear or branched, and/or may be unsaturated (e.g., containing ring(s) and/or C═C bonds).

Exemplary maleimides include aliphatic maleimides (e.g., N-methylmaleimide, N-ethylmaleimide, N-propylmaleimide, N-n-butylmaleimide, N-tert-butylmaleimide, N-pentylmaleimide, N-hexylmaleimide, N-laurylmaleimide, 2-maleimidoethyl ethyl carbonate, or 2-maleimidoethyl isopropyl carbonate); alicyclic maleimides (e.g., N-cyclohexylmaleimide); aromatic maleimides (e.g., N-2-methylphenylmaleimide, N-(2-ethylphenyl)maleimide, N-(4-hydroxyphenyl)maleimide); aliphatic bismaleimides (e.g., N,N′-methylenebismaleimide, N,N′-ethylenebismaleimide, N,N′-trimethylenebismaleimide, N,N′-hexamethylenebismaleimide, N,N′-dodecamethylenebismaleimide, tetraethylene glycol-bis(3-maleimidepropyl) ether, and bis(2-maleimideethyl)carbonate); alicyclic bismaleimides such as 1,4-bismaleimidocyclohexane and isophoronebisurethanebis(N-ethylmaleimide); aromatic bismaleimides (e.g., 1,1′-(methylenedi-4,1-phenylene)bismaleimide, N, N′-(4,4′-diphenyloxy)bismaleimide, N,N′-p-phenylenebismaleimide, N,N′-m-phenylenebismaleimide, N,N′-2,4-tolylenebismaleimide, N,N′-2,6-tolylenebismaleimide, N,N′-[4,4′-bis(3,5-dimethylphenyl)methane]bismaleimide, N,N′-[4,4′-bis(3,5-diethylphenyl)methane]bismaleimide).

In some embodiments of the present invention (e.g., low viscosity compositions such as, for example, ink jet printable compositions), the maleimide is preferably non-polymeric and/or has a molecular weight of less than about 1000 grams per mole.

The benzophenone derivative, acylphosphine oxide, and maleimide are preferably selected such that they are soluble in the photocurable composition and are substantially not reactive with other components of the photocurable composition in the absence of actinic radiation.

Typically, the combined amount of benzophenone derivative, acylphosphine oxide, and maleimide is in a range of from about 0.01 to about 20 weight percent, preferably in a range of from about 3 to about 12 weight percent, more preferably in a range of from about 4 to about 10 weight percent, based on the combined weight of polymerizable material, benzophenone derivative, acylphosphine oxide, and maleimide that is present. The amounts of benzophenone derivative and acylphosphine oxide may be any amounts falling within the abovementioned limitation, but preferably the weight ratio of benzophenone derivative to acylphosphine oxide is in a range of from about 1:5 to about 10:1. More preferably, the weight ratio of benzophenone derivative to acylphosphine oxide is in a range of from about 1:3 to about 5:1.

Likewise, the maleimide may be any amount falling within the abovementioned limitation, but preferably the amount of maleimide is in a range of from about 0.01 percent by weight to about 5 percent by weight, more preferably in a range of from about 0.5 percent by weight to about 2.5 percent by weight, more preferably in a range of from about 0.8 percent by weight to about 2 percent by weight based on the combined weight of polymerizable material, benzophenone derivative, acylphosphine oxide, and maleimide that is present.

Sensitizers, co-initiators, and amine synergists can, optionally, be included in photocurable compositions of the present invention in order to improve the curing rate. Examples include isopropylthioxanthone, ethyl 4-(dimethylamino)benzoate, 2-ethylhexyl dimethylaminobenzoate, and dimethylaminoethyl methacrylate.

Photocurable compositions of the present invention may, optionally, include one or more colorants. Useful colorants include dyes and pigments, which may be used alone or in any combination. Useful dyes and pigments may be of any color, and are well known in the art, for example, as described in U.S. Pat. Nos. 6,294,592 (Herrmann et al.) and 6,114,406 (Caiger et al.), the disclosures of which are incorporated herein by reference. Preferably, the colorant comprises at least one pigment. The amount of optional colorant(s) used in photocurable compositions of the present invention is typically less than about 25 volume percent based on the total volume of the ink composition, although higher volume percentages may be used. Preferably, the colorant(s), if present, is in an amount in a range of from about 0.1 percent by volume to about 15 percent by volume, based on the total volume of the ink composition.

Photocurable compositions of the present invention may, optionally, contain solvent. Solvent may consist of one or more non-reactive diluent materials that may serve, for example, to lower the viscosity of photocurable composition, lower the surface tension of the photocurable composition, and/or dissolve components in the photocurable composition. Any amount of solvent may be utilized. In some embodiments of the present invention, small quantities of solvent may be added as described, for example, in PCT Publication No. WO 02/38687 A1 (Ylitalo et al.), published May 16, 2002, the disclosure of which is incorporated herein by reference. In some embodiments of the present invention, the amount of optional solvent incorporated is kept to a minimum, preferably essentially none (e.g., less than about one weight percent). Exemplary solvents include water; alcohols such as isopropyl alcohol (IPA) or ethanol; ketones such as methyl ethyl ketone, cyclohexanone, or acetone; aromatic hydrocarbons; isophorone; butyrolactone; N-methyl pyrrolidone; tetrahydrofuran; ethers such as lactates, acetates, and the like; ester solvents such as propylene glycol monomethyl ether acetate (PM acetate), diethylene glycol ethyl ether acetate (DE acetate), ethylene glycol butyl ether acetate (EB acetate), dipropylene glycol monomethyl acetate (DPM acetate), iso-alkyl esters, isohexyl acetate, isoheptyl acetate, isooctyl acetate, isononyl acetate, isodecyl acetate, isododecyl acetate, isotridecyl acetate or other iso-alkyl esters; combinations of these, and the like.

In addition to the abovementioned components, one or more other optional additives may be incorporated into photocurable compositions of the present invention. Exemplary additives may, for example, include one or more of colorants, slip modifiers, thixotropic agents, foaming agents, antifoaming agents, flow or other rheology control agents, waxes, oils, plasticizers, binders, antioxidants, stabilizers, electrical conductive agents, fungicides, bactericides, organic and/or inorganic filler particles, leveling agents, opacifiers, antistatic agents, and/or dispersants.

Photocurable compositions of the present invention may be cured, for example, by exposure to actinic radiation (i.e., radiation having a wavelength in the ultraviolet or visible region of the spectrum). Suitable sources of actinic radiation include mercury lamps, xenon lamps, carbon arc lamps, tungsten filament lamps, lasers, electron beam energy, sunlight, microwave driven lamps, and the like. Preferably, the source of radiation is a medium pressure mercury lamp.

Photocurable compositions of the present invention may be applied (e.g., coated, printed) onto a substrate. Exemplary application methods include spraying, dip coating, bar coating, curtain coating, roll coating, gravure coating. In some embodiments of the present invention (e.g., those embodiments wherein the photocurable composition contains at least one colorant), the photocurable composition may be printed onto a substrate. Useful printing techniques include those known in the graphic arts including, for example, screen printing, gravure printing, flexography, lithography, or ink jet printing. The photocurable compositions may be printed, for example, to form graphic elements, text items, continuous layers, bar codes, or other features.

In one embodiment, photocurable compositions of the present invention can be applied to a substrate using an ink jet printhead. The ink jet printhead may be operated at an elevated temperature (e.g., piezo printing). Preferably, the photocurable composition has a viscosity of less than or equal to about 35 millipascal-seconds at the ink jet printhead operating temperature (e.g., less than or equal to about 80° C.) and shear conditions (e.g., 800 per second). Exemplary ink jet printing methods include thermal ink jet, piezo ink jet, continuous ink jet, and bubble jet techniques. Piezo ink jet printing may be especially useful in some embodiments of the present invention.

Further details concerning curable ink jet printable compositions and methods for printing them may be found in, for example, U.S. Pat. Publication No. 2002/0085056 (Ylitalo), published Jul. 4, 2002, the disclosure of which is incorporated herein by reference.

Photocurable compositions of the present invention may be applied to (e.g., coated, printed) a substrate. Useful substrates may be rigid or flexible. Exemplary substrates include wood, metal (including foils), paper (including resin coated papers), textiles (including woven or nonwoven fabrics), polymer films (including vinyl films (e.g., those marketed under the trade designation “SCOTCHCAL” by 3M Company), multilayered films (e.g., as described in, for example, U.S. Pat. Nos. 6,180,228 (Bruno et al.), the disclosure of which is incorporated herein by reference), retroreflective films (e.g., as described in, for example, U.S. Pat. Nos. 6,350,035 (Smith et al.) and 6,221,496 (Yutaka), the disclosures of which are incorporated herein by reference), multilayer polyolefin based films (e.g., as described in, for example, U.S. Pat. Nos. 6,200,647 (Emslander et al.) and 5,721,086 (Emslander et al.), the disclosures of which are incorporated herein by reference), and combinations thereof.

The present invention will be more fully understood with reference to the following non-limiting examples in which all parts, percentages, ratios, and so forth, are by weight unless otherwise indicated.

### EXAMPLES

1,1′-(Methylenedi-4,1-phenylene)bismaleimide (i.e., BM1) and N-methylmaleimide (i.e., NMM) were obtained from Aldrich Chemical Company.

The following abbreviations are used throughout the Examples:

| | |
|---|---|
| SUBSTRATE A | reflective sheeting having the trade designation |
| | “SCOTCHLITE HIGH INTENSITY |
| | REFLECTIVE SHEETING SERIES 3870”, |
| | obtained from 3M Company |
| SUBSTRATE B | adhesive backed polyolefin-based film having |
| | the trade designation “CONTROLTAC PLUS |
| | CHANGEABLE GRAPHIC FILM 3540C”, |
| | obtained from 3M Company |
| SUBSTRATE C | adhesive backed white vinyl film having the |
| | trade designation “CONTROLTAC PLUS |
| | GRAPHIC FILM 180-10”, obtained from 3M |
| | Company |
| SUBSTRATE D | air laid polyester nonwoven fabric having a |
| | polyester scrim, 3.6 ounces per square yard |
| | (120 grams per square meter), obtained under |
| | the trade designation “W4347” from The |
| | Stearns Technical Textiles Company, Roswell, |
| | Georgia |
| SUBSTRATE E | a spunlaced polyester/nylon (50/50 by weight); |
| | 50 grams per square meter non-woven fabric, |
| | obtained from Green Bay Nonwovens, Green |
| | Bay, Wisconsin |
| SUBSTRATE F | a woven cotton wiper having the trade |
| | designation “TX-309”, obtained from ITW |
| | Texwipe Company, Kernersville, North |
| | Carolina |

Photocurable compositions in the following examples were prepared by placing all ingredients in an amber glass jar and allowing the mixture to roll on a roller mill overnight to provide a completely homogeneous solution.

Photocurable compositions were coated onto a 15-centimeter (cm)×20 cm piece of SUBSTRATE C using a number 8 wire wound rod (obtained from RD Specialties, Webster, N.Y.) resulting in a nominal coating thickness of from 8 to 10 micrometers.

The coated films were cured in one pass using an RPC model QC120233AN/DR UV processor, obtained from RPC Industries, Plainfield, Ill. The minimum speed of the processor belt was 30 feet per minute (9 meters per minute). The processor was equipped with two medium pressure mercury lamps with an intensity of 400 watts per inch (160 watts per centimeter). The coating was considered cured if it passed both of the following tests:

1) Cotton applicator test: a cotton tipped applicator was rubbed ten times by hand with firm pressure against the coating (or until smearing of the coating was observed). If no smearing was observed and no cotton fibers transferred to the coating, then the cotton applicator test was passed.

2) Thumb print test: a thumb was pressed with moderate pressure against the coating, twisted 90 degrees, then lifted off the coating. If no marring of the coating surface was visually discerned, then the thumb print test was passed.

Stock Solution:

The following ingredients (in the amounts indicated) were mixed to prepare a stock solution used in the examples below: 3000 parts of an aliphatic urethane diacrylate (obtained under the trade designation “EBECRYL 284” from UCB Radcure, Smyrna, Ga.), 3000 parts of an amine modified polyester acrylate (obtained under the trade designation “EBECRYL 80” from UCB Radcure), 5250 parts of isooctyl acrylate (obtained from 3M Company), 5250 parts of isobornyl acrylate (obtained from Sartomer Company, Exton, Pennsylvania), and 3000 parts of tetrahydrofurfuryl acrylate (obtained from Sartomer Company).

### Comparative Example A

A solution was prepared consisting of 10 parts of stock solution, 0.4 parts of benzophenone (obtained from UCB Radcure), and 0.4 parts of 2,4,6-trimethylbenzoyldiphenylphosphine oxide photoinitiator (obtained under the trade designation “CHIVACURE TPO” from Chitec Chemical Company, Taipei, Taiwan).

### Comparative Example B

A solution was prepared consisting of 98.2 parts of stock solution and 1.8 parts of BM1.

### Examples 1-7

Maleimides BM1 and NMM were added in amounts specified in Table 1 (below) to seven solutions identical to that of Comparative Example A.

TABLE 1

| | | MALEIMIDE | MAXIMUM CURE |
|---|---|---|---|
| | | CONTENT, | SPEED, |
| | MALEIMIDE | percent by | feet per minute |
| EXAMPLE | USED | weight | (meters per minute) |
| COMPARATIVE | none | 0 | 90 (27) |
| EXAMPLE A | | | |
| COMPARATIVE | BM1 | 1.80 | <30 (<9.1) |
| EXAMPLE B | | | |
| EXAMPLE 1 | BM1 | 0.23 | 110 (34) |
| EXAMPLE 2 | BM1 | 0.46 | 120 (37) |
| EXAMPLE 3 | BM1 | 0.92 | 120 (37) |
| EXAMPLE 4 | BM1 | 1.82 | 150 (46) |
| EXAMPLE 5 | NMM | 0.09 | 110 (34) |
| EXAMPLE 6 | NMM | 0.92 | 100 (30) |
| EXAMPLE 7 | NMM | 8.47 | 80 (24) |

### Comparative Example C

A yellow millbase was prepared by pre-dissolving 25 parts of a dispersant (obtained under the trade designation “SOLSPERSE 32000” from Zeneca, Inc., Wilmington, Del.) in 35 parts tetrahydrofurfuryl acrylate (obtained from Sartomer Company) and then adding 40 parts of yellow pigment, obtained under the trade designation “FANCHON FAST YELLOW Y-5688” from Bayer Corporation, Pittsburgh, Pa. Initial wetting of the pigment was accomplished using high shear mixing. Next, the dispersion was subjected to high energy milling in order to reduce the particle size to less than 0.5 microns. A photocurable ink formulation was prepared by combining 7.5 parts of the yellow millbase, 82.5 parts of stock solution, 5 parts of benzophenone, and 5 parts of bis(2,4,6-trimethylbenzoyl)phenylphosphine oxide (i.e., “IRGACURE 819”) in a jar, and placing the jar on a roller mill overnight to provide a homogenous photocurable ink.

### Examples 8-9

BM1 and NMM were added in amounts specified in Table 2 (below) to two inks identical to that of Comparative Example C.

TABLE 2

| | | | Maximum |
|---|---|---|---|
| | | | Cure Speed, |
| | Maleimide | Maleimide Content, | feet per minute |
| | Used | percent by weight | (meters per minute) |
| COMPARATIVE | none | 0 | 80 (24) |
| EXAMPLE C | | | |
| EXAMPLE 8 | BM1 | 2 | 130 (40) |
| EXAMPLE 9 | NMM | 0.1 | 105 (32) |

### Example 10

An inkjet ink was prepared in a manner as described in Comparative Example C, except using the following amounts of the components: 185 parts of stock solution, 15 parts of yellow millbase, 10 parts of benzophenone, 10 parts bis(2,4,6-trimethylbenzoyl)phenylphosphine oxide, and 0.1 parts N-methylmaleimide. The ink viscosity was measured at 25° C. using a Model No. CVO 120 HR NF rheometer (cup and bob configuration, CS C25 cup), obtained from Bohlin Instruments, Ltd., East Brunswick, N.J. The ink viscosity was 26 millipascal-seconds at shear rate of 800 per second. The ink surface tension was measured using a Kruss tensiometer, obtained from Kruss USA, Charlotte, N.C., according to the Wilhemy plate method. The ink surface tension at 25° C. was 30.4 millinewtons per meter.

### Examples 11-16

A variety of substrates were mounted onto a translatable X-Y stage and printed at a resolution of 300 dots per inch (760 dots per cm) by 300 dots per inch (760 dots per cm) using a 256 nozzle piezo printhead (obtained under the trade designation “GALAXY” from Spectra, Inc., Hanover, N.H.) equipped with a deaeration lung and operating at a printhead temperature of 55° C. The printhead settings were: 1.25 kilohertz frequency, 145 volts driving voltage, and pulse width of 8 microseconds. Immediately after printing, the printed ink was cured using a UV processor (obtained from Fusion UV Systems, Gaithersburg, Md.) equipped with a D-type lamp delivering a single pass dosage of 200 millijoules per square centimeter. The results are reported in Table 3 (below).

TABLE 3

| | | PASSES REQUIRED TO |
|---|---|---|
| EXAMPLE | SUBSTRATE | CURE PRINTED INK |
| 11 | A | 1 |
| 12 | B | 1 |
| 13 | C | 1 |
| 14 | D | 3 |
| 15 | E | 3 |
| 16 | F | 4 |

Various modifications and alterations of this invention will become apparent to those skilled in the art without departing from the scope and spirit of this invention, and it should be understood that this invention is not to be unduly limited to the illustrated embodiments set forth herein.

What is claimed is:

1. A photocurable composition comprising:
at least one free-radically polymerizable material;
at least one benzophenone derivative;
at least one acylphosphine oxide; and
at least one maleimide having the formula: 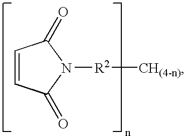
wherein
each R² independently represents a divalent organic group or a covalent bond, and
n is 1, 2, or 3.

2. The photocurable composition of claim 1, wherein R² is alkylene, phenylene, or a covalent bond.

3. The photocurable composition of claim 1, wherein n is 1 or 2.

4. The photocurable composition of claim 1, wherein the at least one polymerizable material is present in an amount of from about 30 percent by weight to about 95 percent by weight, based on the total weight of the polymerizable material.

5. The photocurable composition of claim 1, wherein the at least one polymerizable material is present in an amount of from about 50 percent by weight to about 90 percent by weight, based on the total weight of the polymerizable material.

6. The photocurable composition of claim 1, wherein the at least one polymerizable material comprises at least one of an acrylate monomer or a methacrylate monomer.

7. The photocurable composition of claim 1, wherein the benzophenone derivative is benzophenone.

8. The photocurable composition of claim 1, wherein the at least one acylphosphine oxide comprises at least one of 2,4,6-trimethylbenzoyldiphenylphosphine oxide or bis(2,4,6-trimethylbenzoyl)phenylphosphine oxide.

9. The photocurable composition of claim 1, wherein the at least one maleimide comprises at least one of N-methylmaleimide or 1,1′-(methylenedi-4,1-phenylene)bismaleimide.

10. The photocurable composition of claim 1, wherein the combined amount of benzophenone derivative, acylphosphine oxide, and maleimide is in a range of from about 3 percent by weight to about 12 percent by weight, based on the combined weight of polymerizable material, benzophenone derivative, acylphosphine oxide, and maleimide.

11. The photocurable composition of claim 1, wherein the combined amount of benzophenone derivative, acylphosphine oxide, and maleimide is in a range of from about 4 percent by weight to about 10 percent by weight, based on the combined weight of polymerizable material, benzophenone derivative, acylphosphine oxide, and maleimide.

12. The photocurable composition of claim 1, wherein the weight ratio of benzophenone derivative to acylphosphine oxide is in a range of from about 1:5 to about 10:1.

13. The photocurable composition of claim 1, wherein the amount of maleimide is in a range of from about 0.01 percent by weight to about 5 percent by weight, based on the combined weight of polymerizable material, benzophenone derivative, acylphosphine oxide, and maleimide.

14. The photocurable composition of claim 1, further comprising solvent.

15. The photocurable composition of claim 1, wherein the viscosity is less than or equal to about 35 milliPascal-seconds at 80° C.

16. The photocurable composition of claim 1, further comprising colorant.

17. The photocurable composition of claim 16, further comprising solvent.

18. The photocurable composition of claim 16, wherein the viscosity is less than or equal to about 35 milliPascal-seconds at 80° C.

19. A method for applying a photocurable composition to a substrate comprising:
providing a substrate;
providing a photocurable composition comprising:
at least one free-radically polymerizable material;
at least one benzophenone derivative;
at least one acylphosphine oxide; and
at least one maleimide having the formula: 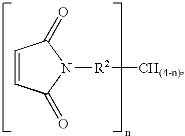
wherein
each R² independently represents a divalent organic group or a covalent bond, and
n is 1, 2, or 3; and
applying the photocurable composition to the substrate.

20. The method of claim 19, further comprising exposing the photocurable composition to actinic radiation.

21. The method of claim 19, wherein applying comprises printing.

22. The method of claim 19, wherein applying comprises a method selected from the group consisting of screen printing, flexographic printing, and ink jet printing.

23. The method of claim 19, wherein applying comprises ink jet printing.

24. The method of claim 19, wherein the photocurable composition further comprises colorant.

25. The method of claim 24, further comprising exposing the photocurable composition to actinic radiation.

26. The method of claim 24, wherein applying comprises printing.

27. The method of claim 24, wherein applying comprises a method selected from the group consisting of screen printing, flexographic printing, and ink jet printing.

28. The method of claim 24, wherein applying comprises ink jet printing.

29. The method of claim 25, wherein the actinic radiation is supplied by a medium pressure mercury lamp.

30. The method of claim 24, wherein the substrate comprises woven fabric.

31. The method of claim 24, wherein the substrate comprises non-woven fabric.

32. The method of claim 24, wherein the substrate is retroreflective.

33. The method of claim 24, wherein the substrate comprises a polymeric film.

34. The method of claim 24, wherein the substrate is selected from the group consisting of paper, vinyl film, and retroreflective sheeting.

35. The method of claim 24, wherein the substrate comprises a multilayer polyolefin based film.

36. An article comprising a substrate having thereon a reaction product of a photocurable composition comprising:
at least one free-radically polymerizable material;
at least one benzophenone derivative;
at least one acylphosphine oxide; and
at least one maleimide having the formula: 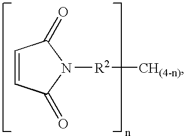
wherein
each R² independently represents a divalent organic group or a covalent bond, and
n is 1, 2, or 3.

37. The article of claim 36, wherein the photocurable composition further comprises colorant.

38. The article of claim 36, wherein the substrate comprises woven fabric.

39. The article of claim 36, wherein the substrate comprises non-woven fabric.

40. The article of claim 36, wherein the substrate is retroreflective.

41. The article of claim 36, wherein the substrate comprises a polymeric film.

42. The article of claim 36, wherein the substrate is selected from the group consisting of paper, vinyl film, and retroreflective sheeting.

43. The article of claim 36, wherein the substrate comprises a multilayer polyolefin based film.
